(19) United States
(12) Patent Application Publication
(10) Pub. No.: US 2008/0160735 A1
(43) Pub. Date: Jul. 3, 2008

(54) Forming Polysilicon Regions

(75) Inventor: Hocine Boubekeur, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/617,359

(22) Filed: Dec. 28, 2006

(51) Int. Cl. H01L 21/3205

(52) U.S. Cl. 438/585

(57) ABSTRACT

Polysilicon regions are formed by performing a thermal treatment in a hydrogen ambient environment after patterning a polysilicon structure.

### BACKGROUND

Semiconductor devices typically include multiple individual components formed on or within a substrate. Such devices often comprise polysilicon regions. For example, the polysilicon regions may form gate electrodes or capacitor electrodes of a memory cell array. These polysilicon regions are often formed by etching openings into polysilicon lines laterally adjoining further material lines. When the polysilicon material is not completely removed within the openings during the etch process, polysilicon residues may provide a continuous connection between neighboring polysilicon regions. These polysilicon residues are also known as poly-stringers and pose a substantial reliability problem, since the poly-stringers can short-circuit neighboring polysilicon regions. The formation of polysilicon regions is therefore crucial and challenging in view of device reliability.

### SUMMARY

A method of forming polysilicon regions is described, where the polysilicon regions can be used, for example, as gate electrodes or capacitor electrodes in a memory cell array. In addition, methods are also described for forming a gate electrode array, a memory device, a memory card and an electronic device.

In an exemplary embodiment, a method of forming polysilicon regions comprises providing, over a surface of a substrate, a polysilicon portion and a support portion that is in contact with the polysilicon portion along a sidewall plane. The method further includes removing a section of the polysilicon portion to partly expose the surface and the sidewall plane and to provide the polysilicon regions, and performing a thermal treatment in a hydrogen ambient environment.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 to 5B show schematic perspective views of a section of a substrate during formation of polysilicon regions according to an embodiment of the present invention.

FIG. 6 shows a schematic view of a memory card according to a further embodiment.

FIG. 7 shows a schematic view of an electronic device according to a further embodiment.

### DETAILED DESCRIPTION

Methods of forming polysilicon regions that can be used, for example, as gate electrodes or capacitor electrodes in a memory cell array are described herein. Further methods of forming a gate electrode array, a memory device, a memory card and an electronic device are also described herein.

In the following description of exemplary embodiments, directional terminology such as “top”, “bottom”, “front”, “back”, “leading”, “trailing”, etc., is used with reference to the orientation of the figures described below. Since components of the embodiments may be positioned in a number of different orientations, the directional terminology is used for purposes of illustration and should in no way be considered limiting. It is to be understood that further embodiments may be utilized and structural or logical changes may be made. The following detailed description, therefore, is not to be taken in a limiting sense.

In an embodiment, a method of forming polysilicon regions comprises providing, over a surface of a substrate, a polysilicon portion and a support portion being in contact with each other along a sidewall plane. The method further includes removing a section of the polysilicon portion to partly expose the surface and the sidewall plane and to provide the polysilicon regions, and performing a thermal treatment in a hydrogen ambient environment (i.e., in hydrogen).

It is noted that any substrate configuration may be used. The substrate may be formed as a semiconductor substrate being pre-processed in any manner. The substrate may include a topology, wherein the topology may be formed by trenches, for example. The substrate may further comprise a layer stack formed on a semiconductor body, for example. The polysilicon portion and the support portion are laterally adjoining each other. The polysilicon portion and the support portion may form a line array of polysilicon lines and support lines extending along a first direction. Removing the section of the polysilicon portion may be carried out by an etch process including an etch mask structure previously formed over the structure. The section, for example, may comprise a sequence of polysilicon portions along the first direction. When removing the polysilicon portions, openings are formed into the polysilicon lines, thereby defining the polysilicon regions. The polysilicon regions may be short-circuited by poly-stringers caused by incomplete removal of polysilicon from the openings. The thermal treatment in the hydrogen ambient environment, also denoted as a hydrogen anneal, may facilitate surface migration of the material of the poly-stringers. Poly-stringers connecting neighboring polysilicon regions can be interrupted as the material of the poly-stringers may form bumps or even migrate to the polysilicon regions due to the hydrogen anneal. Thus, the thermal treatment in the hydrogen ambient environment may avoid short-circuits between neighboring polysilicon regions. The support portion may be formed of an insulating material to which polysilicon can be selectively etched, for example.

According to a further embodiment, a material layer is provided over the polysilicon portion and the support portion and patterned to partly expose the polysilicon portion. The section of the polysilicon portion is removed by etching an exposed part of the polysilicon portion. The patterned material layer or a photoresist structure over the material layer may form an etch mask during patterning of the polysilicon portion.

According to a further embodiment, patterning the material layer and removing the section of the polysilicon portion are carried out by a common etch process. For example, the material layer may also be formed of polysilicon. As an alternative, the material layer may be formed of a material that is different from polysilicon and that may be etched in an etch process removing polysilicon.

A further embodiment relates to a method of forming polysilicon regions, wherein the thermal treatment in the hydrogen ambient environment is performed in a temperature range of 700° C. to 1100° C. The thermal treatment may also be performed in a temperature range of 800° C. to 1000° C. or even 850° C. to 950° C., for example.

According to a further embodiment, the thermal treatment in the hydrogen ambient environment is performed for a time period ranging between 2 seconds and 8 hours. The time period may also range between 1 minute and 1 hour. The time period may be accurately chosen taking into account further process parameters such as the temperature of the thermal treatment, for example.

The polysilicon regions may form gate electrodes of memory cell transistors. The polysilicon regions may also form capacitor electrodes of storage capacitors of DRAM memory cells. Generally, the polysilicon regions may form any kind of structural elements of a semiconductor device comprising an array of device cells.

A further embodiment relates to a method of forming polysilicon regions comprising forming a polysilicon layer over a surface. The polysilicon layer is patterned to provide polysilicon lines separated by trenches extending along a first direction. The trenches are filled with an insulating material and a material layer is formed over the polysilicon lines and the insulating material. After patterning the material layer to provide material lines extending along a second direction intersecting the first direction and to partly expose the polysilicon lines, the polysilicon lines are patterned to provide an array of polysilicon regions, and a thermal treatment in a hydrogen ambient environment is performed.

Patterning the polysilicon layer and the polysilicon lines may be carried out by an etch process, for example. When patterning the polysilicon lines, exposed portions of the polysilicon lines laterally adjoining the insulating material are removed. Thereby, the poly-stringers may be formed as residues due to incomplete removal of the exposed polysilicon portions. Thermal treatment in the hydrogen ambient environment eliminates the poly-stringers as described above. The material layer may be composed of any material including conductive materials such as metals and doped semiconductors. The material layer may also be formed of insulating materials such as oxides or nitrides. When using the material layer to provide word lines or capacitor electrodes, tungsten, polysilicon or tungsten silicide may be used, for example. In case the material layer is used to form a capacitor dielectric, silicon oxide, silicon nitride and high-k dielectrics may be used, for example.

With regard to yet another embodiment, a further thermal treatment in a hydrogen ambient environment is carried out after patterning the material layer and before patterning the polysilicon lines. The further thermal treatment in the hydrogen ambient environment allows smoothing edges of the polysilicon lines, for example.

A further embodiment relates to a method of forming polysilicon regions, wherein the thermal treatment in the hydrogen ambient environment forms at least part of a process involving H₂. When integrating the thermal treatment in the hydrogen ambient environment into an existing process block, an additional thermal budget may be avoided.

According to a further embodiment, the process is a selective oxidation process using H₂ for thermal treatment in the hydrogen ambient environment and, thereafter, a mixture of H₂ and H₂O for selective oxidation. The selective oxidation process may provide a sidewall oxide, for example. The process may first start with the thermal treatment in H₂. When adding H₂O to the H₂ ambient, selective oxidation may be carried out.

According to a further embodiment, the polysilicon regions are gate electrodes of memory cell transistors, and the material lines are word lines.

The polysilicon regions may also form capacitor electrodes of storage capacitors of DRAM memory cells.

A further embodiment relates to a method of forming a gate electrode array, comprising providing forming a gate electrode layer of polysilicon over a surface. The gate electrode layer is patterned to provide gate electrode lines separated by trenches extending along a first direction. The trenches are filled with an insulating layer and a word line layer is formed over the gate electrode lines and the insulating material. The word line layer is patterned to provide word lines extending along a second direction intersecting the first direction and to partly expose the gate electrode lines. After patterning the gate electrode lines to provide an array of gate electrode regions, a thermal treatment in a hydrogen ambient environment is performed.

The word line layer may be formed of a conductive material, for example. Exemplary materials include W, TiN, WN, TaN, Cu, Ta, Al, metal silicides, doped silicon or any combinations thereof.

In a further embodiment, the insulating material is an oxide of silicon forming a bit line oxide.

Above embodiments related to methods of forming polysilicon regions or methods of forming a gate electrode array may be part of a method of forming an integrated circuit.

A further embodiment relates to a method of forming a memory device comprising forming a gate electrode layer of polysilicon over the surface. The gate electrode layer is patterned to provide gate electrode lines separated by trenches extending along a first direction. The trenches are filled with an insulating layer and a word line layer is formed over the gate electrode lines and the insulating material. The word line layer is patterned to provide word lines extending along a second direction intersecting the first direction and to partly expose the gate electrode lines. After patterning the gate electrode lines to provide an array of gate electrode regions a thermal treatment in a hydrogen ambient environment is performed. The method may further include forming a memory cell array comprising memory cell transistors, bit lines and word lines to access the memory cell transistors.

For example, the first and second directions may be perpendicular to each other.

The memory device may be a volatile or non-volatile semiconductor memory device. Exemplary device types include DRAM (Dynamic Random Access Memory), NROM (Nitride Read Only Memory), EPROM (Erasable Programmable Read Only Memory), EEPROM (Electrically Erasable Programmable Read Only Memory) and Flash Memories such as NAND and NOR Flash Memories.

Yet another embodiment relates to a memory card comprising a non-volatile memory device, including a memory cell array comprising memory cell transistors, bit lines and word lines to access the memory cell transistors, wherein polysilicon regions define gate electrodes of the memory cell transistors, the polysilicon regions being provided by forming openings in a structure comprising polysilicon lines and support lines followed by a thermal treatment in a hydrogen ambient environment. The thermal treatment in the hydrogen ambient environment eliminates poly-stringers and prevents short-circuits between neighboring gate electrodes. The thermal treatment causes surface migration of polysilicon material of the poly-stringers dissipating the poly-stringers or completely rearranging the polysilicon material of the former poly-stringers. Thus, the thermal treatment in the hydrogen ambient environment significantly improves the reliability of the non-volatile memory device, and, consequently, the reliability of the memory card.

According to a further embodiment, an electronic device comprises an electronic card interface, a card slot connected to the electronic card interface, and the memory card as defined above, wherein the memory card is adapted to be connected and removed from the card slot. The electronic device may be a cellular phone, a personal computer (PC), a personal digital assistant (PA), a digital still camera, a digital video camera or a portable MP3 player, for example.

It should be noted that, generally, for patterning material layers by etching, a photolithographic method may be used in which a suitable photoresist material is provided. The photoresist material is photolithographically patterned using a suitable photo mask. The patterned photoresist material can be used as a mask during subsequent process steps. For example, as is common, a hard mask layer or a layer made of a suitable material, such as silicon nitride, polysilicon or carbon may be provided over the material layer to be patterned. The hard mask layer is photolithographically patterned using an etch process. Taking the patterned hard mask layer as an etch mask, the material layer is patterned. Patterning of the material layer by etching may also be carried out by using the patterned photoresist material as an etch mask.

The accompanying drawings are included to provide a further understanding of the embodiments of the present invention and are incorporated in and constitute a part of this specification. Other embodiments and many of the intended advantages will be readily appreciated as they become better understood by reference to the following detailed description. The elements of the drawings are not necessarily to scale relative to each other. Like reference numerals designate corresponding similar parts.

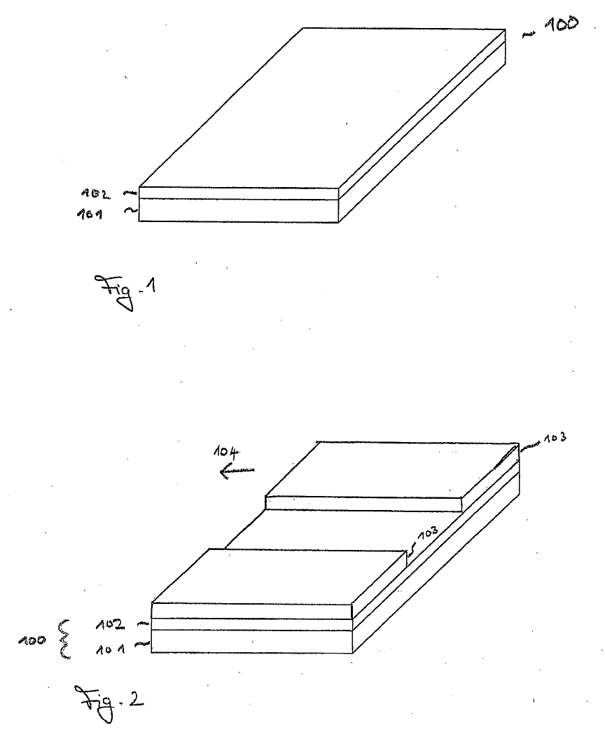

Referring to FIG. 1, a schematic perspective view of a section of a substrate 100 comprising a semiconductor body 101 and a dielectric layer 102 formed thereon is shown. The semiconductor body 101 may be of silicon and the dielectric layer 102 may be an ONO (Oxide-Nitride-Oxide) layer, for example.

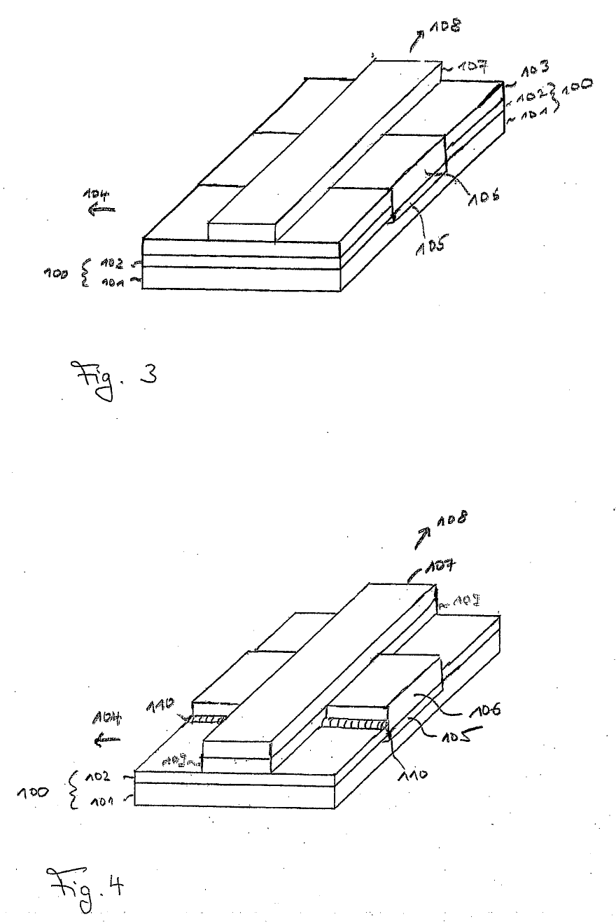

Referring to FIG. 2, a schematic perspective view of the section of the substrate 100 is shown in a later process stage. After providing a polysilicon layer over a surface of the substrate 100 (not shown), the polysilicon layer is patterned to provide polysilicon lines 103 extending along a first direction 104. The patterning of the polysilicon layer may be carried out by an etch process using an etch mask structure (not shown).

Referring to the schematic perspective view of the section of the substrate 100 in FIG. 3, further process features during formation of polysilicon regions will now be described. After formation of the polysilicon lines 103 exposed parts of the dielectric layer 102 may also be removed to expose part of the semiconductor body 101. Thereafter, a semiconductor region 105 may be formed within the semiconductor body 101 by an appropriate method such as implantation or diffusion. The semiconductor region 105 may be a buried bit line, for example. A trench separating neighboring polysilicon lines 103 is then filled with an insulating material 106. The insulating material 106 may be of silicon oxide and may form a bit line oxide. Thereafter, a material layer is formed over a surface of the polysilicon lines 103 and the insulating lines 106 and patterned to provide material lines 107 along a second direction 108 intersecting the first direction 104. The material lines 107 may form word lines, for example. As is recognized by one skilled in the art, a plurality of material lines 108, polysilicon lines 103 and insulating lines 106 may be provided. In the perspective views shown in FIG. 1 to 5, merely a section of the substrate 100 is shown to clearly show relevant aspects or features of the embodiment.

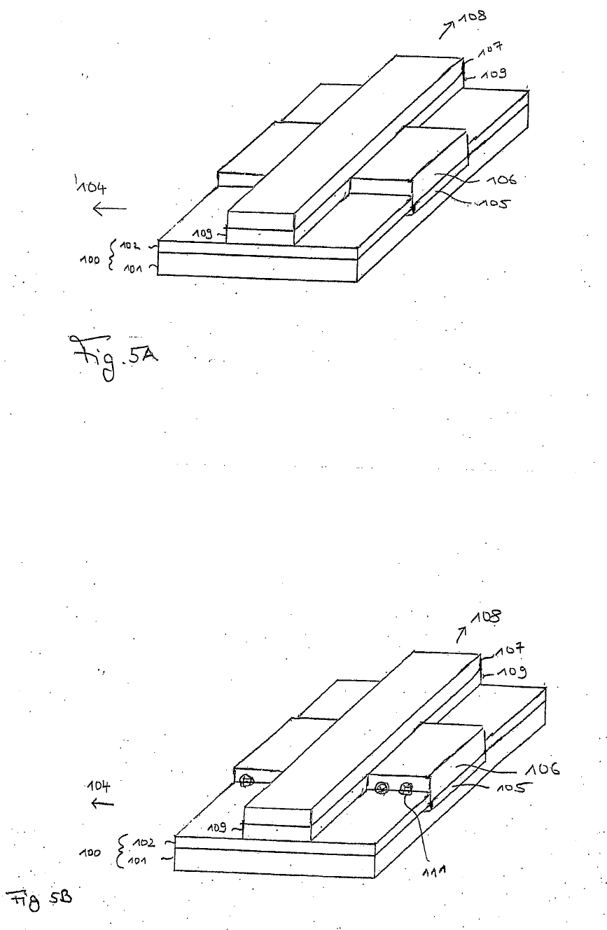

Referring to FIG. 4, a schematic perspective view of the section of the substrate 100 is illustrated with regard to a later process stage during formation of the polysilicon regions. As the material lines 107 merely partly cover the polysilicon lines 103 and the insulating lines 106, as is shown in FIG. 3, exposed parts of the polysilicon lines 103 are removed by etching, thereby providing polysilicon regions 109 arranged along the first and second directions 104, 108. When etching the polysilicon lines 103, polysilicon material may remain as poly-stringers 110 along sidewalls of the insulting lines 106. These poly-stringers 110 are detrimental with regard to a reliability of a device comprising the polysilicon regions 109 as a structural element. The polysilicon regions 109 may form gate electrodes or capacitor electrodes of memory devices, for example.

Referring to FIGS. 5A and 5B, schematic perspective views of the section of the substrate 100 are shown after performing a thermal treatment in a hydrogen ambient environment to eliminate or dissipate the poly-stringers 110, thereby improving the reliability of a semiconductor device including the polysilicon regions as structural elements. As the thermal treatment in hydrogen facilitates migration of silicon material, the polysilicon material of the poly-stringers 110 (shown in FIG. 4) may migrate to the polysilicon regions 109, thereby eliminating the poly-stringers 110. Depending up on process parameters during the thermal treatment such as a temperature and duration of the treatment, the poly-stringers 110 may also contract to polysilicon bumps 111 as is shown in FIG. 5B. These bumps 111 are remainders of the material of the dissipated poly-stringers. Irrespective of the precise relocation of polysilicon material of the poly-stringers 110, shorts between neighboring polysilicon regions 109 can be avoided by the thermal treatment in the hydrogen ambient environment. Thus, a significant improvement with regard to device reliability can be achieved.

Methods of forming polysilicon regions are now described. A polysilicon portion and a support portion, which are in contact with each other along a sidewall plane, are provided over a surface of a substrate. Thereafter, a section of the polysilicon portion is removed to partly expose the surface and the sidewall plane, thereby providing polysilicon regions. Then, a thermal treatment in a hydrogen ambient environment is performed. The thermal treatment in the hydrogen ambient environment facilitates migration of silicon material, thereby eliminating or dissipating the poly-stringers so as to prevent short-circuits between neighbouring polysilicon regions.

A further embodiment of a method of forming polysilicon regions is now generally described. First, a polysilicon layer is formed over a surface. Thereafter, the polysilicon layer is patterned to provide polysilicon lines separated by trenches along a first direction. The trenches are then filled with an insulating material. Thereafter, a material layer is formed over the polysilicon lines and the insulating material and then patterned to provide material lines extending along a second direction intersecting the first direction and to partly expose the polysilicon lines. Thereafter, the polysilicon lines are patterned to provide an array of the polysilicon regions arranged along the first and second directions. Then, a thermal treatment in a hydrogen ambient environment is performed to eliminate or dissipate the poly-stringers between neighboring polysilicon regions.

It is to be noted that the methods described above may be integrated into a process of forming a memory cell array. The polysilicon regions may be used as gate electrodes or capacitor electrodes, for example.

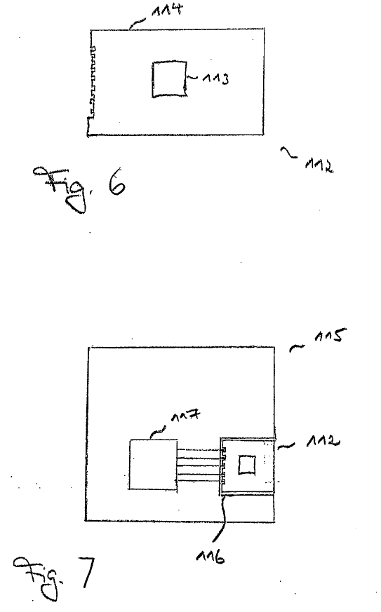

Referring to FIG. 6, a schematic view of a memory card 112 according to a further embodiment is illustrated. The memory card 112 comprises a memory device 113 within a memory card housing 114. The memory device 113 comprises an array of memory cells including polysilicon regions, which may form gate electrodes or capacitor electrodes, for example. The polysilicon regions were thermally treated in a hydrogen ambient environment in order to eliminate or dissipate poly-stringers formed by process technology and to improve the memory device reliability, and, consequently, the reliability of the memory card 112.

Referring to FIG. 7, a schematic view of an electronic device 115 according to a further embodiment is briefly described. The electronic device 115 includes the memory card 112, which is adapted to be connected and removed from a card slot 116 of the electronic device 115. The card slot 116 is connected to an electronic card interface 117 of the electronic device 115. The electronic device 115 may be a cellular phone, a PC, a PDA, a digital still camera, a digital video camera or a portable MP3 player, for example.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of forming polysilicon regions, comprising:
providing, over a surface of a substrate, a polysilicon portion and a support portion, wherein the polysilicon portion and support portion are in contact with each other along a sidewall plane;
removing a section of the polysilicon portion to partly expose the substrate surface and the sidewall plane and to form polysilicon regions; and
performing a thermal treatment in a hydrogen ambient environment.

2. The method of claim 1, wherein the polysilicon portion comprises a linear member extending along a first direction.

3. The method of claim 1, further comprising:
providing a material layer over the polysilicon portion and the support portion;
patterning the material layer to expose sections of the polysilicon portion; and
removing exposed sections of the polysilicon portion via etching.

4. The method of claim 3, wherein patterning the material layer is achieved via etching.

5. The method of claim 1, wherein the thermal treatment in the hydrogen ambient environment is performed at a temperature range from 700° C. to 1100° C.

6. The method of claim 1, wherein the thermal treatment in the hydrogen ambient environment is performed for a time period ranging between 2 seconds and 8 hours.

7. The method of claim 1, wherein the polysilicon regions comprise gate electrodes of memory cell transistors.

8. The method of claim 1, wherein the polysilicon regions comprise capacitor electrodes of storage capacitors of DRAM memory cells.

9. An integrated circuit including polysilicon regions formed according to the method of claim 1.

10. A method of forming polysilicon regions, comprising:
forming a polysilicon layer over a surface;
patterning the polysilicon layer to form polysilicon lines separated by trenches extending along a first direction;
filling the trenches with an insulating material;
forming a material layer over the polysilicon lines and the insulating material;
patterning the material layer to form material lines extending along a second direction intersecting the first direction and to partly expose the polysilicon lines;
patterning the polysilicon lines to provide an array of polysilicon regions; and
performing a thermal treatment in a hydrogen ambient environment.

11. The method of claim 10, wherein the thermal treatment in the hydrogen ambient environment is performed at a temperature range from 700° C. to 1100° C.

12. The method of claim 10, wherein the thermal treatment in the hydrogen ambient environment is performed for a time period ranging between 2 seconds and 8 hours.

13. The method of claim 10, wherein a further thermal treatment in a hydrogen ambient environment is performed after patterning the material layer and before patterning the polysilicon lines.

14. The method of claim 10, wherein the thermal treatment in the hydrogen ambient environment forms part of a process that utilizes H₂.

15. The method of claim 14, wherein the process comprises a selective oxidation process using H₂ for thermal treatment in the hydrogen ambient environment and, thereafter, a mixture of H₂ and H₂O for selective oxidation.

16. The method of claim 10, wherein the insulating material comprises an oxide of silicon.

17. The method of claim 10, wherein the polysilicon regions comprise gate electrodes, and the material lines comprise word lines.

18. The method of claim 10, wherein the insulating material is an oxide of silicon forming a bit line oxide.

19. The method of claim 10, wherein the polysilicon regions comprise capacitor electrodes of storage capacitors of DRAM memory cells.

20. An integrated circuit including polysilicon regions formed according to the method of claim 10.

21. A memory card comprising a non-volatile memory device including a memory cell array comprising memory cell transistors, bit lines and word lines to access the memory cell transistors, wherein polysilicon regions define gate electrodes of the memory cell transistors, the polysilicon regions being provided by forming openings in a structure comprising polysilicon lines and support lines followed by a thermal treatment in a hydrogen ambient environment.

22. An electronic device comprising:
an electronic card interface;
a card slot connected to the electronic card interface; and
the memory card of claim 21, wherein the memory card is adapted to be connected and removed from the card slot.
